(19) United States
(12) Patent Application Publication
(10) Pub. No.: US 2010/0134976 A1
(43) Pub. Date: Jun. 3, 2010

(54) HEAT DISSIPATING PAD STRUCTURE FOR NOTEBOOK COMPUTER

(76) Inventor: Cheng-Ping Kuo, Taipei County (TW)

Correspondence Address: WPAT, PC;INTELLECTUAL PROPERTY ATTORNEYS, 2030 MAIN STREET, SUITE 1300, IRVINE, CA, 92614, US

(21) Appl. No.: 12/327,131

(22) Filed: Dec. 3, 2008

(51) Int. Cl. H05K 7/20

(52) U.S. Cl. 361/695

(57) ABSTRACT

A heat dissipating pad structure of a notebook computer includes a retaining unit, a baffle wall and at least two air guide units (fans). Air can be entered from the bottom of the notebook computer. The external periphery of a ventilation hole is disposed on the baffle wall for enclosing a space area, such that the air guide unit keeps guiding air into the space area to increase the volume of air and produce a positive air pressure, and a fan installed in the notebook computer produces a negative air pressure suction, such that cold air is compressed, sucked and guided simultaneously into the computer for a heat exchange and a discharge of hot air from the interior of the computer, so as to achieve a better heat dissipating effect.

### FIELD OF THE INVENTION

The present invention relates to a heat dissipating pad structure of a notebook computer, and more particularly to a heat dissipating pad structure capable of guiding air into a space area continuously by an air guide unit, such that the volume of air is increased to produce a positive air pressure to guide cold air into a computer and discharge hot air from the interior of the computer to the outside to achieve a better heat dissipating effect.

### BACKGROUND OF THE INVENTION

As notebook computer users generally use a fan type heat dissipating pad for lowering the internal temperature of a computer to extend the life of computer devices, and a traditional notebook computer heat dissipating pad 5 (as shown in FIG. 1) includes a retaining board 51, a support board 52 extended vertically from an edge of the retaining board 51 and at least two fans 53 mounted onto the retaining board 51. When the heat dissipating pad is used as shown in FIGS. 2 and 3, a notebook computer 6 is placed on the retaining board 51 directly, and the fans 53 are provided for guiding air to the bottom of the notebook computer 6 to achieve the heat dissipating effect.

Although the traditional heat dissipating pad 5 can guide airflow to dissipate heat for a notebook computer 6, air may not be guided into the notebook computer 6 to an expected position precisely when the fan 53 guides the airflow directly to the bottom of the notebook computer 6, since different notebook computers 6 come with different specifications, and the fan 53 may or may not be aligned directly with an air inlet of the notebook computer 6. Even if the fan 53 is aligned with the air inlet of the notebook computer 6, a large quantity of airflow cannot be guided directly into the notebook computer 6 and provided for a heat exchange with components in the notebook computer 6, due to the air entering from the bottom of the notebook computer 6, too-small ventilation holes, and too-many turning corners and obstacles. When the notebook computer 6 is placed precisely on the retaining board 51, a gap may occur between the notebook computer 6 and the retaining board 51 due to the foot pad 61, so that a vast majority of wind produced by the air guide unit (fan) is blocked by the bottom of the notebook computer 6 and redirected to positions around the gap (a) and then dispersed.

Therefore, a row of extractor fans (a total of 3˜4 fans in the embodiment) in the notebook computer 6 and the fan 53 of the heating dissipating pad 5 are not coupled with each other directly or closely to provide a system capable of guiding and discharging a large quantity of air.

When guiding air, the fan 53 usually guides an airflow to the bottom of the notebook computer 6 and redirects the airflow to different directions, and then the airflow will stop, and thus the fan 53 can lower the temperature and disperse the heat at the bottom of a chassis of the notebook computer 6 caused by the thermal radiation of the notebook computer 6 and at ventilation holes at the bottom of the notebook computer 6. When the extractor fan in the notebook computer 6 sucks air, a negative air pressure is produced at the neighborhood of the air inlet to suck cold air into the computer through the air inlet disposed at the bottom of the notebook computer 6. In other words, only the extractor fans originally installed in the notebook computer 6 are operated to enter the cold air into the computer, and thus the fan 53 installed on the heat dissipating pad 5 cannot assist the heat dissipation effectively.

According to the Bernoulli's Principle of fluid mechanics, the faster the air flows, the smaller is the air pressure at the air flowing region. This is exactly the basic principle that allows an airplane with wings to fly. Therefore, the stronger the wind of the heat dissipating pad 5, the faster is the wind speed of the wind blown at the bottom of the notebook computer 6 and redirected to different directions. Thus, the air pressure at the bottom of the notebook computer 6 becomes smaller to produce a negative air pressure which will conflict with the negative air pressure at the air inlet caused by the air discharged by the extractor fans inside the notebook computer 6, such that the regions having these negative air pressures will suck air, and it takes even more efforts for the extractor fans in the notebook computer 6 to suck air than the situation of having no fan 53 of the heat dissipating pad 5 at all.

According to the negative air pressure produced by guiding the wind of the heat dissipating pad 5 directly to the bottom of the notebook computer 6 and then redirecting the wind in different directions, the wind has gone through several turning corners and gaps before reaching the air inlet at the bottom of the notebook computer 6, and thus the wind is blocked to a certain extent and gives a weak suction effect of the negative air pressure. As a result, the computer cannot suck in sufficient cold air to perform a heat exchange for discharging the hot air or cool down the interior of the computer. This is the main reason why present heat dissipating pads 5 cannot remove waste heat from the notebook computer 6 effectively.

In addition, the negative air pressure of a quick airflow of the heat dissipating pad also sucks away the air with heat radiations at the neighborhood of the hot air ventilation holes at the regions other than the bottom of the notebook computer 6. Things come with both sides, respectively the good and the bad. The fast airflow discharged by the fan 53 of the heat dissipating pad 5 blocks the cold air from being sucked into the notebook computer 6 to some extent and carries away lots of air with heat radiation at the regions of the heat generating components and regions with a much lower temperature than the CPU. This phenomenon gives us the impression of a low heat dissipating effect of a general heat dissipating pad 5.

At present, the heat dissipating pad products available in the market use a low-power fan or a high-density metal mesh to block the wind and retard the wind speed, such that the air pressure at the bottom of the notebook computer 6 becomes more stable to facilitate sucking air into the computer. Designers do not want to have a too-strong airflow between the bottom of the computer and the heat dissipating pad, and just need to keep the airflow produced by the heat dissipating pad fan within a range sufficient to drive the heat radiation of air at the bottom of the notebook computer 6 and introduce cold air, and the rest will leave to the internal extractor fans alone for sucking the cold air into the computer by the weak suction force at the air inlet. If the airflow at the bottom of the computer 6 is too large, it will reduce the efficiency of sucking air into the notebook computer 6.

Compared with the sucking and discharging devices and the heat dissipating function of present existing traditional heat dissipating pads available in the market, the sucking and discharging devices of the improved heat dissipating pad assembly of the invention definitely have a different working principle to improve the working efficiency.

### SUMMARY OF THE INVENTION

Therefore, it is a primary objective of the present invention to provide a heat dissipating pad assembly having a baffle wall disposed around the external periphery of all air inlets and ventilation holes at the bottom of a notebook computer for enclosing a space area to achieve the effect of integrating the extractor fan in the computer with the heat dissipating pad fan, such that an air guide unit can keep guiding air into the space area to increase the volume of air to produce a positive air pressure. With the suction of a negative air pressure produced by the extractor fan installed in the notebook computer, cold air is compressed, sucked and guided into the computer for performing a heat exchange with the heat generating components and discharge the hot air from the interior of the computer, so as to achieve a better heat dissipating effect.

To achieve the foregoing objective, the present invention provides an improved heat dissipating pad structure of a notebook computer, comprising a retaining unit, a baffle wall and at least two air guide units (fans), wherein the retaining unit includes a retaining board, at least two through holes (air outlets) disposed on the retaining board, and a support board extended downward from an edge of the retaining board; the baffle wall is disposed around the retaining board, and the air guide units (fans) are disposed in the through holes of the retaining board respectively. Air can be entered from the bottom of the notebook computer. The external periphery of a ventilation hole is disposed on the baffle wall for enclosing a space area, such that the air guide unit (fan) keeps guiding air into the space area to increase the volume of air and produce a positive air pressure, and a fan installed in the notebook computer produces a negative air pressure suction, such that cold air is compressed, sucked and guided simultaneously into the computer for a heat exchange and a discharge of hot air from the interior of the computer, so as to achieve a better heat dissipating effect.

### BRIEF DESCRIPTION OF THE DRAWINGS

FIG. 1 is a perspective view of a prior art;

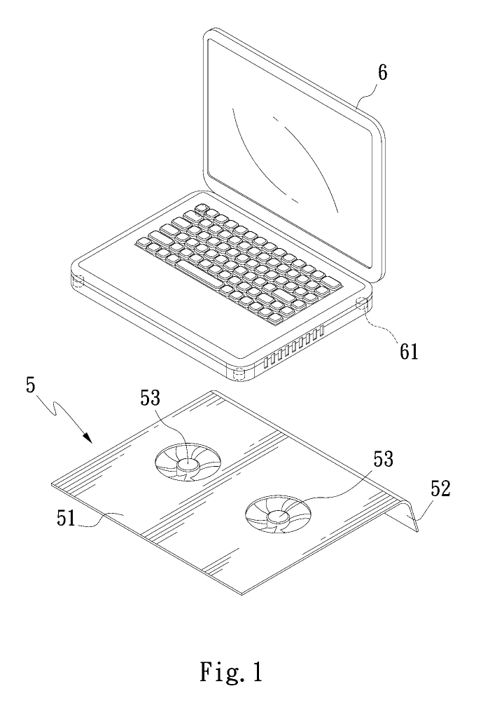

FIG. 2 is a schematic view of an application of a prior art;

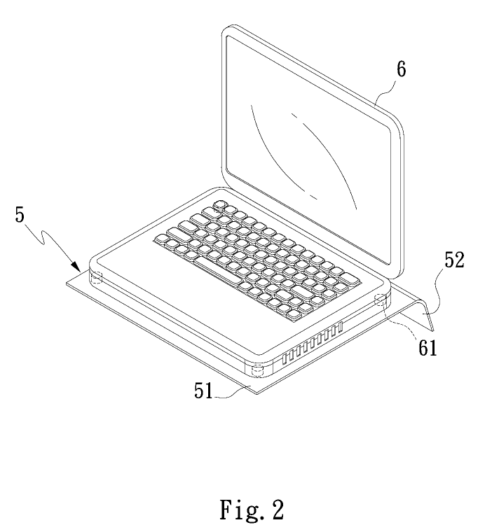

FIG. 3 is a cross-sectional view of an application of a prior art;

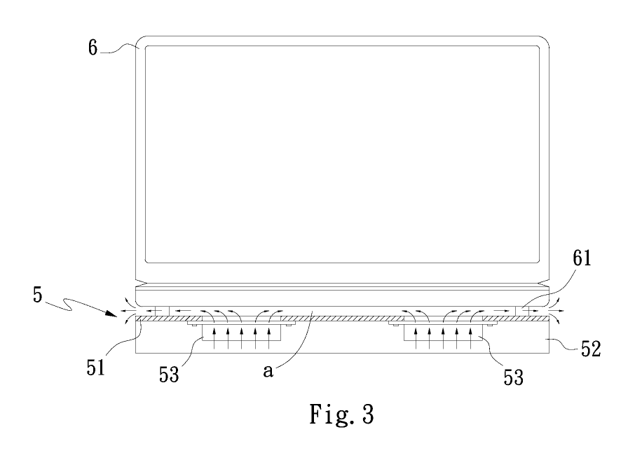

FIG. 4 is a perspective view of the present invention; and

FIG. 5 is a cross-sectional view of an application of the present invention.

### DESCRIPTION OF THE PREFERRED EMBODIMENT

Other features and advantages of the present invention will become apparent in the following detailed description of the preferred embodiments with reference to the accompanying drawings.

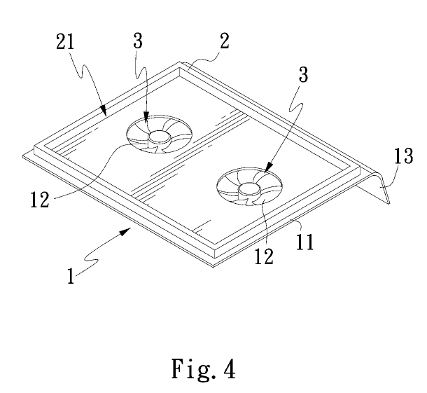

With reference to FIG. 4 for a perspective view of the present invention, an improved heat dissipating pad structure of a notebook computer comprises a retaining unit 1, a baffle wall 2 and at least two air guide unit 3.

The retaining unit 1 includes a retaining board 11, at least two through holes 12 disposed on the retaining board 11, and a support board 13 extended downward from an edge of the retaining board 11.

The baffle wall 2 is disposed around the retaining board 11 for enclosing the periphery of the through holes 12 on the retaining board 11, such that the internal side of the baffle wall 2 encloses the lower half of the space area 21 of each through hole 12, and the top of the baffle wall can support the bottom of the notebook computer 4, and the baffle wall 2 is made of a natural plant secretion or an industrial petroleum manufactured product including latex, rubber, silica gel, plastic, foam sponge, polylon and silicon, or air cushion, water cushion, cardboard, wood, metal, cloth, Velcro tape, or a composite, a mixture, or a compound of the above.

Each air guide unit 3 is disposed in each through hole 12 on the retaining board 11, such that the aforementioned structure constitutes a novel improved heat dissipating pad structure of a notebook computer.

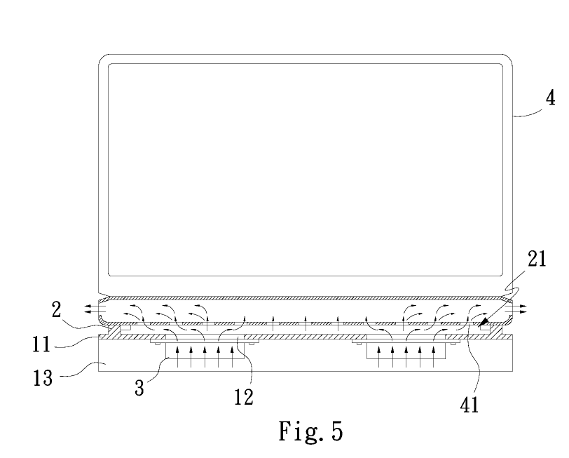

With reference to FIG. 5 for a cross-sectional view of an application of the present invention, the notebook computer 4 is placed on the retaining unit 1 for the use of the heat dissipating pad, such that air is entered from the bottom of the notebook computer 4, and the periphery of the ventilation hole abuts the baffle wall 2 for coupling the bottom of the notebook computer 4 and the baffle wall 2 and enclosing the space area 21. The original air entered from the bottom of the notebook computer 4 and the ventilation hole 41 is aligned with the corresponding space area 21.

The so-called “enclosing the space area 21” refers to the space area 21 becoming a place of increasing the air pressure of the air by means of the baffle wall, instead of an airtight seal. However, the function of increasing the air pressure varies with the shape of the baffle wall, the material used for making the baffle wall, and the degree of the tight coupling with the bottom of the notebook computer, and thus the level of increasing the air pressure will vary.

During a heat dissipation process, each air guide unit 3 keeps guiding the air produced during the operation into space area 21, and the volume of air in the space area 21 is increased to produce a positive air pressure since the space area 21 is in an enclosed form, such that the cold air brought in by each air guide unit 3 is compressed. In addition, a pulling force of the negative air pressure produced by the extractor fan in the notebook computer 4 sucks the cold air through all air inlets and ventilation holes 41 at the bottom of the notebook computer 4 into the notebook computer 4, while compressing the cold air.

The cold air flows into the notebook computer 4 through the air inlet and ventilation hole 41 at the bottom of the notebook computer 4, and then flows to an air discharging hole 42 on the lateral side of the notebook computer 4 for performing a heat exchange with each heat generating component of the notebook computer 4. The air with absorbed heat is discharged by the pulling force of the extractor fan in the computer and the compressing force of the positive air pressure of the space area 21, such that hot air can be discharged out from the air discharging hole 42 of the computer.

Therefore, the compressing force of the positive air pressure produced by the enclosed space area 21 and the pulling force of the negative air pressure caused by extractor fan of the notebook computer 4 can greatly increase the airflow of the cold air entering into the notebook computer 4 to enhance the heat dissipating and cooling effects significantly.

Unlike the airflow of the air blown directly from a fan of a traditional heat dissipating pad, the cold air flowing according to the pressure gradient will not be blocked by obstacles or gaps that will eliminate or reduce the air speed and airflow. Regardless of the complicated path inside the notebook computer 4, the air entered from the bottom of the notebook computer 4 or the size of the ventilation holes, the airflow provided by the heat dissipating pad of the invention still flows from high air pressure to low air pressure.

In general, a notebook computer 4 comes with a specification of installing a row of fans (not shown in the figure) and thus the synergy of the air guide units 3 and a total of approximately 3 to 4 fans can be maximized to achieve a better heat dissipating effect. Since the enclosed space area 21 formed by the baffle wall covers all air inlets and ventilation holes at the bottom of the notebook computer 4, and thus the cold air entered from the space area 21 into the computer is dispersed in different directions and all over the interior of the computer, instead of performing a heat exchange of the heat generating CPU and peripherals by a heat sink only. Therefore, such heat dissipating method can dissipate the heat of the entire computer. All components of the computer including the motherboard, CPU, hard disk drive, display card, burner, memory, power supply and various different chips can have a direct heat exchange with the cold air to achieve the cooling effect.

In summation of the description above, the improved heat dissipating pad structure of a notebook computer in accordance with the present invention overcomes the shortcomings of the prior art by building a baffle wall around the periphery of the bottom of a notebook computer for enclosing a space area, such that an air guide unit can keep guiding air into the space area to increase the volume of air and produce a positive air pressure, and a fan installed in the notebook computer produces suctions by a negative air pressure, such that cold air is compressed, sucked and guided simultaneously into the computer for a heat exchange and a discharge of hot air from the interior of the computer, so as to achieve a better heat dissipating effect. The present invention complies with the patent application requirements, and thus is duly filed for patent application.

While the invention has been described by means of specific embodiments, numerous modifications and variations could be made thereto by those skilled in the art without departing from the scope and spirit of the invention set forth in the claims.

What is claimed is:

1. A heat dissipating pad structure of a notebook computer, comprising:
a retaining unit, including a retaining board, at least two through holes disposed on the retaining board, and a support board extended downward from an edge of the retaining board;
a baffle wall, disposed around the retaining board, and proximate to the periphery of the retaining board, for forming a space area within the internal sides of the baffle wall and interconnected to each through hole; and
at least two air guide units, disposed in the through holes of the retaining board respectively.

2. The improved heat dissipating pad structure of a notebook computer as recited in claim 1, wherein the baffle wall is made of a natural plant secretion or an industrial petroleum manufactured product including latex, rubber, silica gel, plastic, foam sponge, polylon and silicon, or air cushion, water cushion, cardboard, wood, metal, cloth, Velcro tape, or a composite, a mixture, or a compound of the above.
